(19) United States
(12) Patent Application Publication
(10) Pub. No.: US 2026/0038595 A1
(43) Pub. Date: Feb. 5, 2026

(54) MEMORY DEVICE FOR PERFORMING PROGRAM OPERATION AND METHOD OF OPERATING THE SAME

(71) Applicant: SK hynix Inc., Gyeonggi-do (KR)

(72) Inventors: Chang Hyun HAN, Gyeonggi-do (KR); Moon Soo SUNG, Gyeonggi-do (KR)

(21) Appl. No.: 19/052,308

(22) Filed: Feb. 13, 2025

(30) Foreign Application Priority Data
Aug. 1, 2024 (KR) 10-2024-0102533

(51) Int. Cl. G11C 16/10; G11C 16/04; G11C 16/08; G11C 16/34

(52) U.S. Cl. CPC G11C 16/10; G11C 16/0483; G11C 16/08; G11C 16/349

(57) ABSTRACT

A memory device may include a memory block including a plurality of memory cell strings, each including a source select transistor, a plurality of memory cells, and a drain select transistor; a peripheral circuit configured to perform a program operation of precharging the memory cell strings and applying a program voltage to a selected word line among a plurality of word lines; and a control logic configured to determine a first voltage based on information related to threshold voltages of memory cells which are not programmed yet, and control, while precharging the plurality of memory cell strings, the peripheral circuit to apply the first voltage to at least one first word line coupled to the memory cells which are not programmed yet, and apply a second voltage higher than the first voltage to the selected word line and at least one second word line coupled to programmed memory cells.

### CROSS-REFERENCE TO RELATED APPLICATION

The present application claims priority under 35 U.S.C. § 119 (a) to Korean patent application number 10-2024-0102533 filed on Aug. 1, 2024, the entire disclosure of which is incorporated by reference herein.

### BACKGROUND

### 1. Field of Invention

Various embodiments of the present disclosure generally relate to a semiconductor device, and more particularly to a memory device for performing a program operation and a method of operating the memory device.

### 2. Description of Related Art

Memory devices are configured to store data therein, and are generally classified into volatile memory devices and nonvolatile memory devices.

A memory device may perform a program operation of storing data in memory cells. For example, the memory device may program memory cells coupled to a selected word line by applying a program voltage to the selected word line. Furthermore, a negative boosting effect that occurs in a channel region of a memory cell string may be reduced by precharging the memory cell string before the program voltage is applied. The negative boosting effect may be a phenomenon in which the channel region of the memory cell string is lowered to a negative state.

During a process of precharging the memory cell string, when a ground voltage is applied to memory cells that have not yet been programmed, the precharge level of the memory cell string may be limited to the threshold voltage level of memory cells that have not yet been programmed. When each of the threshold voltages of memory cells that have not yet been programmed is high, the performance of the operation of precharging the memory cell string may be decreased. Further, during the process of precharging the memory cell string, when the same voltage as the voltage to be applied to programmed memory cells is applied to memory cells that have not yet been programmed, current consumption may increase, the time it takes for each of the threshold voltages of memory cells to reach a target voltage may increase, and a disturbance effect may occur in memory cells that have not yet been programmed. The disturbance effect may be a phenomenon in which the threshold voltages of memory cells fluctuate.

### SUMMARY

Various embodiments of the present disclosure are directed to a memory device capable of efficiently performing a precharge operation on memory cell strings, and a method of operating the memory device.

An embodiment of the present disclosure may provide for a memory device. The memory device may include a memory block including a plurality of memory cell strings, each including a source select transistor, a plurality of memory cells, and a drain select transistor sequentially coupled between a common source line and a bit line; a peripheral circuit configured to perform a program operation of precharging the plurality of memory cell strings and thereafter applying a program voltage to a selected word line among a plurality of word lines coupled to the plurality of memory cells; and a control logic configured to determine a first voltage based on information related to threshold voltages of memory cells which are not programmed yet by the program operation, among the plurality of memory cells, and control, while precharging the plurality of memory cell strings, the peripheral circuit to apply the first voltage to one or more first word lines coupled to the memory cells which are not programmed yet, among the plurality of word lines, and apply a second voltage higher than the first voltage to the selected word line and at least one second word line coupled to memory cells programmed by the program operation, among the plurality of word lines.

An embodiment of the present disclosure may provide for a memory device. The memory device may include a memory block including a plurality of memory cell strings, each memory cell string including a plurality of memory cells coupled to a plurality of word lines, the memory block being coupled to the plurality of word lines, a source select line, and a drain select line; a peripheral circuit configured to perform a program operation of precharging the plurality of memory cell strings while applying a first voltage to at least one first word line coupled to memory cells which are not programmed yet, among the plurality of word lines, and applying a program voltage to a selected word line among the plurality of word lines; and a control logic configured to determine a default voltage based on a position of the selected word line, determine an offset voltage based on at least one of a temperature of the memory device and a program-erase cycle count of the memory block, and determine the first voltage by adding the offset voltage to the default voltage.

An embodiment of the present disclosure may provide for a method of operating a memory device, the memory device including a plurality of memory cell strings, each memory cell string including a source select transistor, a plurality of memory cells, and a drain select transistor sequentially coupled between a common source line and a bit line. The method may include generating a first voltage based on information related to threshold voltages of memory cells which are not programmed yet by a program operation, among the plurality of memory cells, applying the first voltage to at least one first word line coupled to the memory cells that have not yet been programmed, among the plurality of word lines, precharging the plurality of memory cell strings while applying the first voltage to the first word lines, and applying a program voltage to a selected word line among the plurality of word lines.

### BRIEF DESCRIPTION OF THE DRAWINGS

FIG. 1 is a diagram illustrating a memory device according to an embodiment of the present disclosure.

FIG. 2 is a diagram illustrating a program operation according to an embodiment of the present disclosure.

FIG. 3 is a diagram illustrating a precharge operation performed on a plurality of memory cell strings according to an embodiment of the present disclosure.

FIG. 4 is a diagram illustrating voltages applied during a program voltage apply operation according to an embodiment of the present disclosure.

FIGS. 5A and 5B are diagrams illustrating a first voltage determined based on the position of a selected word line according to an embodiment of the present disclosure.

FIG. 6 is a diagram illustrating a first voltage determined based on the temperature of a memory device according to an embodiment of the present disclosure.

FIG. 7 is a diagram illustrating a first voltage determined based on the program-erase cycle count of a memory block according to an embodiment of the present disclosure.

FIGS. 8A, 8B, and 8C are diagrams illustrating a first voltage determined based on at least one of the position of a selected word line, the temperature of a memory device, and the program-erase cycle count of a memory block according to an embodiment of the present disclosure.

FIG. 9 is a flowchart illustrating a method of operating a memory device according to an embodiment of the present disclosure.

### DETAILED DESCRIPTION

Specific structural or functional descriptions of the embodiments of the present disclosure introduced in this specification are provided as examples to describe embodiments according to the concept of the present disclosure. The embodiments according to the concept of the present disclosure may be practiced in various forms, and should not be construed as being limited to the embodiments described in this specification.

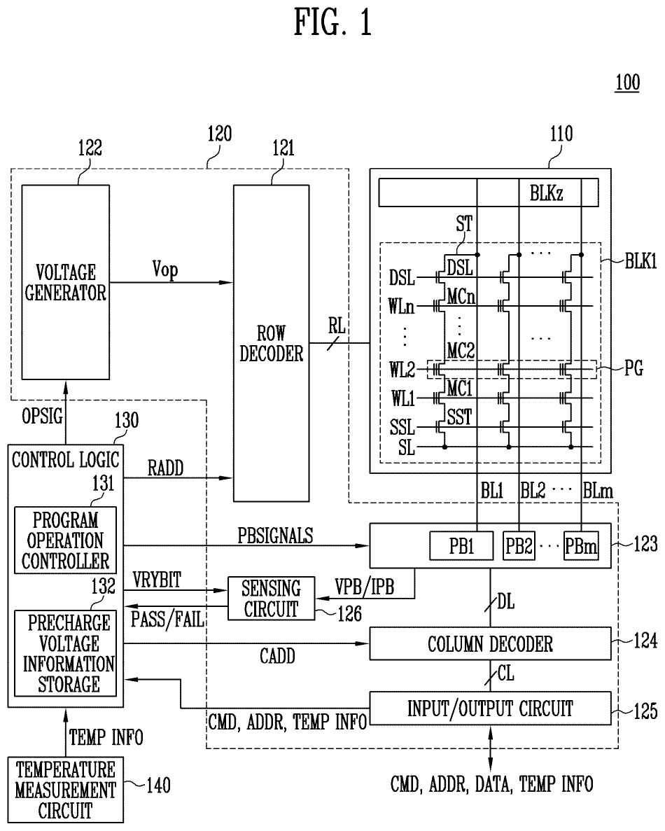

FIG. 1 is a diagram illustrating a memory device according to an embodiment of the present disclosure.

Referring to FIG. 1, a memory device 100 may include a memory cell array 110, a peripheral circuit 120, a control logic 130, and a temperature measurement circuit 140.

The memory cell array 110 includes a plurality of memory blocks BLK1 to BLKz.

The plurality of memory blocks BLK1 to BLKz are connected to a row decoder 121 through row lines RL. Here, the row lines RL may include at least one source select line SSL, a plurality of word lines WL1 to WLn, and at least one drain select line DSL. The source select line SSL may be connected to a source select transistor SST, and the drain select line DSL may be connected to a drain select transistor DST. The source select transistor SST may be controlled through the source select line SSL, and the drain select transistor DST may be controlled through the drain select line DSL.

Each of the memory blocks BLK1 to BLKz may include a plurality of memory cells MC1 to MCn. The plurality of memory cells MC1 to MCn may be connected to a page buffer circuit 123 through a plurality of bit lines BL1 to BLm.

Each of the plurality of memory blocks BLK1 to BLKz may include a plurality of memory cell strings ST connected between the bit lines BL1 to BLm and a common source line CSL. Each of the memory cell strings ST may include at least one source select transistor SST, a plurality of memory cells MC1 to MCn, and at least one drain select transistor DST which are connected in series to each other between the common source line CSL and a corresponding one of the bit lines BL1 to BLm. The plurality of memory cells MC1 to MCn may be connected between the common source line CSL and any bit line BL1. The source select transistors SST may be connected between the common source line CSL and the plurality of memory cells MC1 to MCn. The drain select transistors DST may be connected between the bit line BL1 and the plurality of memory cells MC1 to MCn.

Each of the memory cells MC1 to MCn may be connected to any of the plurality of word lines WL1 to WLn. Memory cells connected to the same word line may be defined as one page (PG). Each of the memory cells MC1 to MCn may store a plurality of data bits.

The peripheral circuit 120 may perform a program operation, a read operation, or an erase operation on a selected area of the memory cell array 110 under the control of the control logic 130.

The peripheral circuit 120 may include the row decoder 121, a voltage generator 122, the page buffer group 123, a column decoder 124, an input/output circuit 125, and a sensing circuit 126.

The row decoder 121 may decode a row address RADD received from the control logic 130. The row decoder 121 selects at least one of the memory blocks BLK1 to BLKz according to the decoded address. Further, the row decoder 121 may select at least one word line of the memory block selected according to the decoded address. The row decoder 121 may apply voltages Vop generated by the voltage generator 122 to the selected word line.

The voltage generator 122 may generate a plurality of voltages using an external supply voltage provided to the memory device 100. In detail, the voltage generator 122 may generate various operating voltages Vop that are used for program, read, and erase operations in response to an operation signal OPSIG. The plurality of generated voltages Vop may be supplied to the memory cell array 110 by the row decoder 121.

The page buffer group 123 may include a plurality of page buffers PB1 to PBm. The plurality of page buffers PB1 to PBm may temporarily store data received through the plurality of bit lines BL1 to BLm or sense the voltages or currents of the plurality of bit lines BL1 to BLm during a read or verify operation, in response to page buffer control signals PBSIGNALS.

The column decoder 124 may transfer data between the input/output circuit 125 and the page buffer group 123 in response to a column address CADD.

The input/output circuit 125 may transmit a command CMD, an address ADDR, and temperature information TEMP INFO, received from a memory controller (not illustrated), to the control logic 130, or may exchange data DATA with the column decoder 124. The temperature information TEMP INFO may include the temperature of the memory device 100 measured by the memory controller.

The sensing circuit 126 may determine whether a verify operation for a specific program state has passed with the application of a verify voltage.

In an embodiment, the sensing circuit 126 may perform a check operation of determining whether the verify operation has passed based on data sensed from the plurality of memory cells MC1 to MCn while a program voltage is applied to a word line.

In an example, during the verify operation, the sensing circuit 126 may generate a reference current in response to an enable bit signal VRYBIT, and may compare a sensing voltage VPB received from the page buffer group 123 with a reference voltage generated by the reference current and then output a pass signal PASS or a fail signal FAIL. In an example, during the verify operation, the sensing circuit 126 may generate a reference voltage in response to the enable bit signal VRYBIT, and may compare a sensing current IPB received from the page buffer group 123 with a reference current generated by the reference voltage and then output a pass signal PASS or a fail signal FAIL.

The control logic 130 may control the peripheral circuit 120 by outputting the operation signal OPSIG, the row address RADD, and the page buffer control signals PBSIGNALS in response to the command CMD and the address ADDR.

In an embodiment, the control logic 130 may include a program operation controller 131 and a precharge voltage information storage 132.

The program operation controller 131 may control a program operation of the memory device 100. For example, the program operation controller 131 may provide the operation signal OPSIG for controlling the generation of a program voltage, a verify voltage, etc. to the voltage generator 122, and may generate the row address RADD by decoding the address ADDR of a word line in which data DATA is to be stored.

In an embodiment, the program operation controller 131 may perform a program operation on selected memory cells connected to the selected word line, among the plurality of memory cells MC1 to MCn. Here, the selected word line may be a word line connected to the selected memory cells that are the target of the program operation. For example, the program operation controller 131 may apply the program voltage to the selected word line, and may perform a verify operation on the selected memory cells.

In an embodiment, the program operation controller 131 may precharge the plurality of memory cell strings ST before applying the program voltage to the selected word line.

In an embodiment, the program operation controller 131 may determine a first voltage based on information related to the threshold voltages of memory cells that have not yet been programmed by the program operation, among the plurality of memory cells MC1 to MCn.

In an embodiment, the information related to the threshold voltages of memory cells that have not yet been programmed may include various types of environment information influencing the threshold voltages of the memory cells that have not yet been programmed. For example, the information related to the threshold voltages of memory cells that have not yet been programmed may include at least one of the position of the selected word line, the temperature of the memory device 100, and the number of program-erase cycles (i.e., program-erase cycle count) of the memory block. Here, the position of the selected word line may include the distance from the source select line SSL or the drain select line DSL to the selected word line. The program-erase cycle count may refer to the number of cycles, each composed of a program operation and an erase operation that are performed on the memory block. The program operation controller 131 may receive the temperature information of the memory device 100 from the temperature measurement circuit 140 or the memory controller.

In an embodiment, the program operation controller 131 may determine the first voltage before the program operation is performed on the selected memory cells connected to the selected word line. For example, the program operation controller 131 may determine the first voltage after receiving the command CMD, the address ADDR, and the data DATA from the memory controller. The program operation controller 131 may perform the program operation on the selected memory cells after determining the first voltage.

Further, the program operation controller 131 may control the peripheral circuit 120 to apply the first voltage to one or more first word lines connected to the memory cells that have not yet been programmed by the program operation while the plurality of memory cell strings ST are being precharged.

Further, the program operation controller 131 may control the peripheral circuit 120 to apply a second voltage higher than the first voltage to at least one second word line, connected to memory cells programmed by the program operation, and to the selected word line while the plurality of memory cell strings ST are being precharged.

The precharge voltage information storage 132 may store information on the first voltage determined depending on the information related to the threshold voltages of the memory cells that have not yet been programmed.

In an embodiment, the precharge voltage information storage 132 may store a first voltage table indicating a mapping relationship between the position of the selected word line and the first voltage.

In an embodiment, the precharge voltage information storage 132 may store a first voltage table indicating a mapping relationship between the temperature of the memory device 100 and the first voltage.

In an embodiment, the precharge voltage information storage 132 may store a first voltage table indicating a mapping relationship between the program-erase cycle count of the memory block and the first voltage.

The program operation controller 131 may obtain information on the first voltage or the first voltage table from the precharge voltage information storage 132.

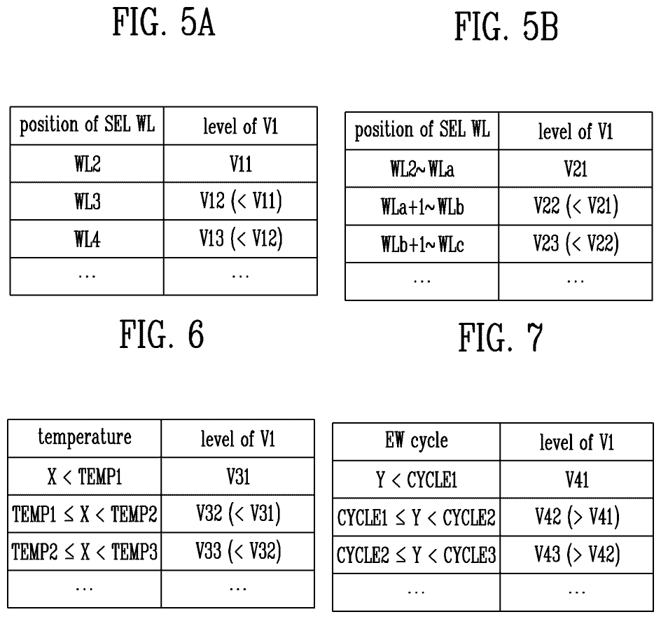

The information on the first voltage or the first voltage table, stored in the precharge voltage information storage 132, will be described in detail later with reference to FIGS. 5A, 5B, 6, 7, and 8A to 8C.

The temperature measurement circuit 140 may measure the temperature of the memory device 100. The temperature measurement circuit 140 may provide the temperature information TEMP INFO of the memory device 100 to the control logic 130.

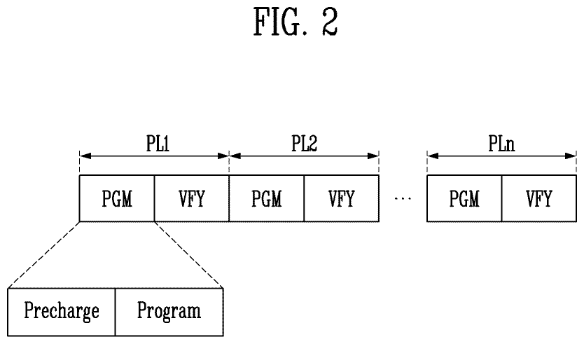

FIG. 2 is a diagram illustrating a program operation according to an embodiment of the present disclosure.

Referring to FIG. 2, for convenience of description, each of a plurality of memory cells is a multi-level cell MLC in which 2-bit data is stored. However, the scope of the present disclosure is not limited thereto, and each of the plurality of memory cells may be a triple-level cell (TLC) in which 3-bit data is stored, or a quad-level cell (QLC) in which 4-bit data is stored.

A program operation of the memory device 100 may include a plurality of program loops PL1 to PLn. That is, the memory device 100 may program each of selected memory cells to have a threshold voltage corresponding to one of a plurality of program states by performing the plurality of program loops PL1 to PLn.

Each of the plurality of program loops PL1 to PLn may include a program voltage apply operation PGM of applying a program voltage to the selected word line and a verify operation VFY of applying verify voltages to verify whether the memory cells have been programmed.

The program voltage apply operation PGM included in each program loop may include a precharge period (Precharge) and a program period (Program). Although not illustrated in FIG. 2, the program voltage apply operation PGM according to an embodiment may further include a discharge period during which voltages applied to word lines and select lines are discharged.

During the precharge period (Precharge), an operation of precharging the plurality of memory cell strings is performed. The operation of precharging the plurality of memory cell strings may be referred to as a “string precharge operation”.

Furthermore, during the precharge period (Precharge), an operation of setting a bit line voltage that is the voltage applied to a plurality of bit lines may be performed. The operation of setting the bit line voltage may be referred to as a “bit line setup operation.”

The bit line setup operation may include an operation of setting the bit line voltage to a program-enable voltage or a program-inhibit voltage. As a program pulse is applied to the selected word line during a subsequent program period (Program), each memory cell connected to the bit line set to the program-enable voltage may have an increased threshold voltage. Furthermore, during the subsequent program period (Program), the threshold voltage of a memory cell connected to the bit line set to the program-inhibit voltage may be maintained.

In an embodiment, the program-enable voltage may be a ground voltage, and the program-inhibit voltage may be a supply voltage.

The string precharge operation may include an operation of transferring a voltage applied from the common source line or each bit line to the plurality of memory cell strings.

The program period may be a period during which each selected memory cell is programmed to have a threshold voltage corresponding to a program state. For example, the memory device 100 may apply the program voltage to the selected word line and apply a program pass voltage having a level lower than that of the program voltage to unselected word lines. Furthermore, the memory device 100 may apply a ground voltage corresponding to 0 V to a selected bit line, and may apply the supply voltage to an unselected bit line. Accordingly, the memory device 100 may allow each selected memory cell to have the threshold voltage corresponding to the program state.

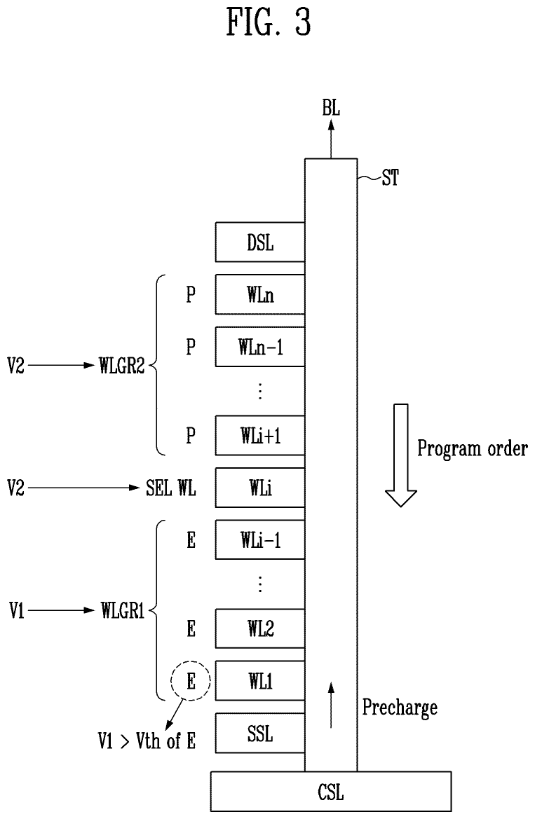

FIG. 3 is a diagram illustrating a precharge operation performed on a plurality of memory cell strings according to an embodiment of the present disclosure. A bit line BL illustrated in FIG. 3 may be one of the plurality of bit lines BL1 to BLm, illustrated in FIG. 1. Although, in FIG. 3, only one memory cell string ST is illustrated, description made with reference to FIG. 3 may be equally applied to all memory cell strings ST included in a memory block.

Referring to FIG. 3, first to i−1-th word lines WL1 to WLi−1 may be a first word line group WLGR1. Memory cells connected to the first to i−1-th word lines WL1 to WLi−1 may be memory cells E that have not yet been programmed.

Further, i+1-th to n-th word lines WLi+1 to WLn may be a second word line group WLGR2. Memory cells connected to the i+1-th to n-th word lines WLi+1 to WLn may be programmed memory cells P.

Furthermore, an i-th word line WLi may be a selected word line SEL WL. The memory cells connected to the i-th word line WLi may be memory cells to be programmed through the program operation.

In an embodiment, the program operation may start from the n-th word line WLn adjacent to the drain select line DSL, and may be performed last on the first word line WL1 adjacent to the source select line SSL. This may be referred to as a reverse order.

Unlike the example illustrated in FIG. 3, the program operation may start from the first word line WL1 adjacent to the source select line SSL, and may be performed last on the n-th word line WLn adjacent to the drain select line DSL. This may be referred to as a forward order. In the present specification, description will be made on that the program operation is performed according to the reverse order.

In an embodiment, the memory device 100 may precharge the memory cell string ST through a common source line CSL. For example, the memory device 100 may precharge the channel region of the memory cell string ST through the common source line CSL and the source select line SSL in the state in which the source select transistor connected to the source select line SSL is turned on. Here, the drain select transistor connected to the drain select line DSL may be in a turned-off state. That is, in order to reduce disturbance during a program operation, the memory device 100 may precharge a plurality of memory cell strings before a program voltage is applied.

Because a voltage for precharging the corresponding memory cell string ST is transferred to the common source line CSL, the voltage may be transferred to the entire channel region of the memory cell string ST through the memory cells E connected to the first word line group WLGR1. In this case, in order to smoothly perform a precharge operation on the memory cell string ST, the memory cells E connected to the first word line group WLGR1 need to be smoothly turned on. That is, the memory cells E may be smoothly turned on to form the channel region through which current can flow only when the voltage applied through the word line connected to the gates of the memory cells is higher than the threshold voltage Vth of each of the memory cells E.

In an embodiment, the memory device 100 may apply a first voltage V1 to the first word line group WLGR1 and apply a second voltage V2 to the second word line group WLGR2 and the selected word line SEL WL while the memory cell string ST is precharged.

In an embodiment, the first voltage V1 may be higher than a ground voltage. Further, the first voltage V1 may be a voltage higher than the threshold voltage Vth of each of the memory cells E that have not yet been programmed. For example, the first voltage V1 may be determined based on the threshold voltage Vth of each of the memory cells E that have not yet been programmed. In detail, the first voltage V1 may be determined based on various types of environment information influencing the threshold voltages Vth of the memory cells E that have not yet been programmed. Such environment information may include the position of the selected word line SEL WL, the temperature of the memory device 100, the program-erase cycle count of the memory block, etc. Further, the first voltage V1 may be lower than the second voltage V2.

Therefore, the precharge operation on the memory cell strings ST may be efficiently performed by determining the first voltage V1 based on the threshold voltages Vth of the memory cells E that have not yet been programmed.

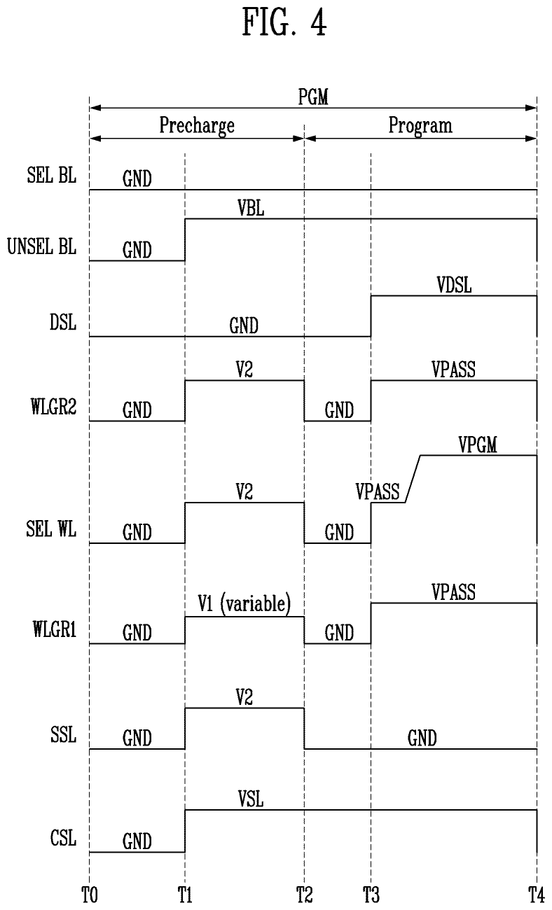

FIG. 4 is a diagram illustrating voltages applied during a program voltage apply operation according to an embodiment of the present disclosure.

Referring to FIG. 4, an operation during a period from T0 to T2 may indicate a precharge period (Precharge) included in a program voltage apply operation PGM, and an operation during a period from T2 to T4 may indicate a program period (Program) included in the program voltage apply operation PGM.

Respective lines illustrated in FIG. 4 may represent the lines illustrated in FIG. 3.

In an embodiment, a selected bit line SEL BL may be a bit line connected to program-enabled memory cells through the program voltage apply operation PGM, and an unselected bit line UNSEL BL may be a bit line connected to program-inhibited memory cells on which programming has been completed.

From TO, the memory device 100 may start the program voltage apply operation PGM.

At T1, the memory device 100 may apply a ground voltage GND to the selected bit line SEL BL. Here, the ground voltage GND applied to the selected bit line SEL BL may be used as a program-enable voltage.

Further, the memory device 100 may apply a precharge voltage VBL for precharging bit lines to the unselected bit line UNSEL BL. Here, the precharge voltage VBL applied to the unselected bit line UNSEL BL may be used as a program-inhibit voltage.

Furthermore, the memory device 100 may apply a source voltage VSL for precharging a plurality of memory cell strings to the common source line CSL. The voltage level of the common source line CSL may be increased by the source voltage VSL.

In an embodiment, the memory device 100 may apply a first voltage V1 to a first word line group WLGR1. The first voltage V1 may vary based on at least one of the position of a selected word line SEL WL, the temperature of the memory device 100, and the program-erase cycle count of the memory block. The memory cells, which are connected to the first word line group WLGR1 and have not yet been programmed, may be turned on by the first voltage V1.

In an embodiment, the memory device 100 may apply a second voltage V2 to a second word line group WLGR2 and to the selected word line SEL WL. The second voltage V2 may be higher than the first voltage V1. By the second voltage V2, memory cells connected to the second word line group WLGR2 and the selected word line SEL WL may be turned on.

The memory device 100 may apply a ground voltage GND for turning off the drain select transistor to the drain select line DSL.

Further, the memory device 100 may apply the second voltage V2 for turning on the source select transistor to the source select line SSL.

At T2, the memory device 100 may apply the ground voltage GND to the first word line group WLGR1, the second word line group WLGR2, and the selected word line SEL WL.

The memory device 100 may maintain the drain select line DSL at the ground voltage GND, and may apply the ground voltage GND to the source select line SSL.

Furthermore, the memory device 100 may maintain the common source line CSL at the source voltage VSL.

At T3, the memory device 100 may apply a pass voltage VPASS to the selected word line SEL WL and thereafter apply a program voltage VPGM thereto. The selected memory cells connected to the selected word line SEL WL may be programmed by the program voltage VPGM.

Furthermore, the memory device 100 may apply the pass voltage VPASS to the first word line group WLGR1 and the second word line WLGR2.

Furthermore, the memory device 100 may apply a voltage VDSL for turning on the drain select transistor to the drain select line DSL.

Furthermore, the memory device 100 may maintain the source select line SSL at the ground voltage GND.

In addition, the memory device 100 may maintain the common source line CSL at the source voltage VSL.

FIGS. 5A and 5B are diagrams illustrating a first voltage determined based on the position of a selected word line according to an embodiment of the present disclosure. In detail, FIG. 5A is a diagram for describing the first voltage V1 determined for each position of a selected word line SEL WL, and FIG. 5B is a diagram for describing the first voltage V1 determined for each area to which the position of the selected word line SEL WL belongs.

In an embodiment, the position of the selected word line SEL WL may include the distance from a word line, connected to memory cells to be programmed last, among one or more first word lines, to the selected word line SEL WL. In an example, when a program operation is performed according to a reverse order, the position of the selected word line SEL WL may include the distance from the first word line WL1 to the selected word line SEL WL. In an example, when a program operation is performed according to a forward order, the position of the selected word line SEL WL may include the distance from the n-th word line WLn to the selected word line SEL WL. Hereinafter, for convenience of description, the case where the program operation is performed according to the reverse order will be described by way of example.

In an embodiment, the memory device 100 may increase a level of the first voltage V1 as the distance between the word line connected to the memory cells to be programmed last and the selected word line SEL WL is shorter.

Referring to FIG. 5A, as the distance between the first word line WL1 and the selected word line SEL WL is shorter, the level of the first voltage V1 may increase.

For example, when the selected word line SEL WL corresponds to the second word line WL2, the level of the first voltage V1 may correspond to an 11-th voltage V11.

Furthermore, when the selected word line SEL WL corresponds to a third word line WL3, the level of the first voltage V1 may correspond to a 12-th voltage V12. Because the distance between the first word line WL1 and the second word line WL2 is shorter than the distance between the first word line WL1 and the third word line WL3, the 11-th voltage V11 may be higher than the 12-th voltage V12.

When the selected word line SEL WL corresponds to a fourth word line WL4, the level of the first voltage V1 may correspond to a 13-th voltage V13. Because the distance between the first word line WL1 and the third word line WL3 is shorter than the distance between the first word line WL1 and the fourth word line WL4, the 12-th voltage V12 may be higher than the 13-th voltage V13.

Consequently, when the selected word line SEL WL corresponds to an n-th word line WLn, the first voltage V1 may be the lowest, whereas when the selected word line SEL WL corresponds to the second word line WL2, the first voltage V1 may be the highest.

Referring to FIG. 5B, as the distance between the first word line WL1 and the area to which the position of the selected word line SEL WL belongs is shorter, the level of the first voltage V1 may increase.

For example, when the selected word line SEL WL belongs to an area including second to a-th word lines WL2 to WLa, the level of the first voltage V1 may correspond to a 21-th voltage V21.

When the selected word line SEL WL belongs to an area including a+1-th to b-th word lines WLa+1 to WLb, the level of the first voltage V1 may correspond to a 22-th voltage V22. Because the distance between the first word line WL1 and the area including the a+1-th to b-th word lines WLa+1 to WLb is shorter than the distance between the first word line WL1 and the area including the second to a-th word lines WL2 to WLa, the 21-th voltage V21 may be higher than the 22-th voltage V22.

Further, when the selected word line SEL WL belongs to an area including b+1-th to c-th word lines WLb+1 to WLc, the level of the first voltage V1 may correspond to a 23-th voltage V23. Because the distance between the first word line WL1 and the area including the second to a-th word lines WL2 to WLa is shorter than the distance between the first word line WL1 and the area including the b+1-th to c-th word lines WLb+1 to WLc, the 22-th voltage V22 may be higher than the 23-th voltage V23.

FIG. 6 is a diagram illustrating a first voltage determined based on the temperature of a memory device according to an embodiment of the present disclosure.

In an embodiment, the memory device 100 may decrease a level of a first voltage V1 as the temperature X of the memory device 100 increases.

Referring to FIG. 6, when the temperature X of the memory device 100 is lower than first temperature TEMP1, the level of the first voltage V1 may correspond to a 31-th voltage V31.

When the temperature X of the memory device 100 is equal to or higher than the first temperature TEMP1 and lower than second temperature TEMP2, the level of the first voltage V1 may correspond to a 32-th voltage V32. Here, the 32-th voltage V32 may be lower than the 31-th voltage V31.

When the temperature X of the memory device 100 is equal to or higher than the second temperature TEMP2 and lower than third temperature TEMP3, the level of the first voltage V1 may correspond to a 33-th voltage V33. Here, the 33-th voltage V33 may be lower than the 32-th voltage V32.

Consequently, when the temperature X of the memory device 100 is the highest, the first voltage V1 may be the lowest, whereas when the temperature X of the memory device 100 is the lowest, the first voltage V1 may be the highest.

FIG. 7 is a diagram illustrating a first voltage determined based on the program-erase cycle count of a memory block according to an embodiment of the present disclosure.

In an embodiment, the memory device 100 may increase a level of a first voltage V1 as the number of program-erase cycles (i.e., program-erase cycle count Y) of the memory block increases.

Referring to FIG. 7, when the program-erase cycle count Y of the memory block is less than a first cycle count CYCLE1, the level of the first voltage V1 may correspond to a 41-th voltage V41.

When the program-erase cycle count Y of the memory block is equal to or greater than the first cycle count CYCLE1 and less than a second cycle count CYCLE2, the level of the first voltage V1 may correspond to a 42-th voltage V42. The 42-th voltage V42 may be higher than the 41-th voltage V41.

When the program-erase cycle count Y of the memory block is equal to or greater than the second cycle count CYCLE2 and less than a third cycle count CYCLE3, the level of the first voltage V1 may correspond to a 43-th voltage V43. The 43-th voltage V43 may be higher than the 42-th voltage V42.

Consequently, when the program-erase cycle count Y of the memory block is the lowest, the first voltage V1 may be the lowest, whereas when the program-erase cycle count Y of the memory block is the highest, the first voltage V1 may be the highest.

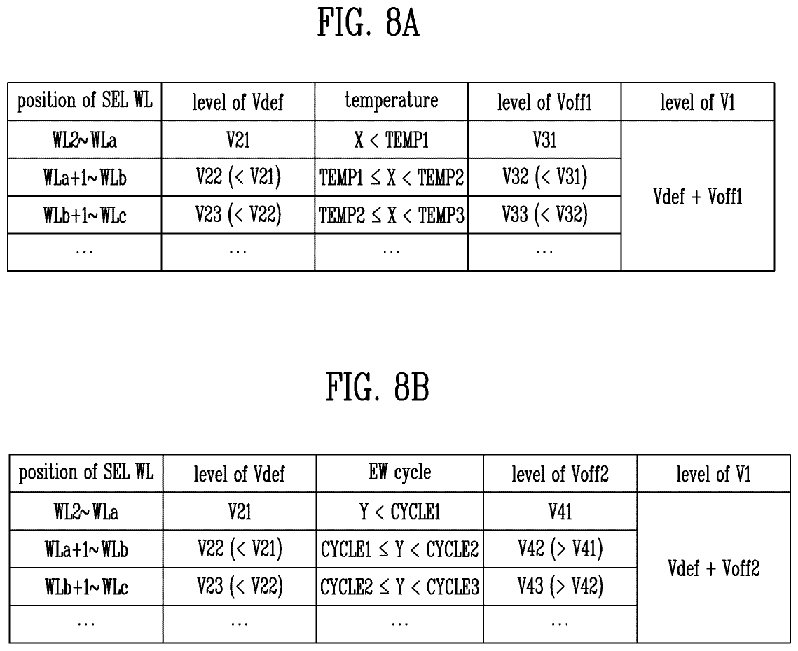

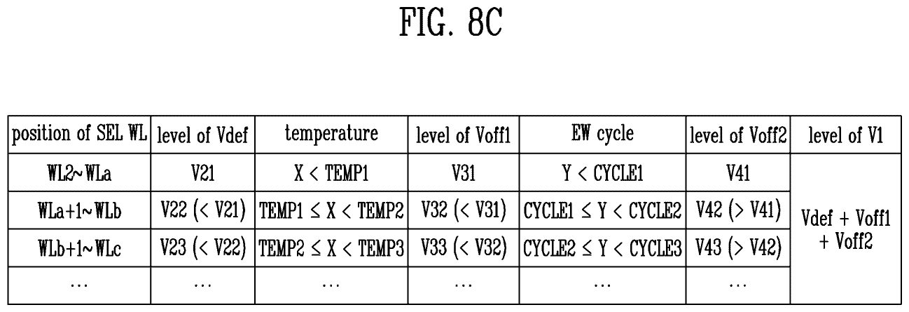

FIGS. 8A, 8B, and 8C are diagrams illustrating a first voltage determined based on at least one of the position of a selected word line, the temperature of a memory device, and the program-erase cycle count of a memory block according to an embodiment of the present disclosure. In FIGS. 8A, 8B, and 8C, for convenience of description, an example in which a voltage corresponding to the position of the selected word line is determined based on the example illustrated in FIG. 5B may be illustrated. However, embodiments to be described with reference to FIGS. 8A, 8B, and 8C, may be equally applied to the example in which a voltage corresponding to the position of the selected word line is determined based on the example illustrated in FIG. 5A. Further, in FIGS. 8A, 8B, and 8C, description will be made on that a program operation is performed according to a reverse order.

In an embodiment, the memory device 100 may determine a default voltage based on the position of a selected word line. Furthermore, the memory device 100 may determine an offset voltage based on at least one of the temperature of the memory device and the program-erase cycle count of a memory block. Further, the memory device 100 may determine the first voltage by adding the offset voltage to the default voltage.

In an embodiment, the memory device 100 may increase a level of the default voltage Vdef as the distance between a word line connected to memory cells to be programmed last and a selected word line SEL WL is shorter.

In an embodiment, the memory device 100 may decrease a level of a first offset voltage Voff1 as the temperature X of the memory device 100 increases.

In an embodiment, the memory device 100 may increase a level of a second offset voltage Voff2 as the program-erase cycle count Y of the memory block increases.

In an embodiment, FIG. 8A is a diagram for describing an example in which the first voltage is determined based on the position of the selected word line and the temperature of the memory device.

Referring to FIG. 8B, as the distance between a first word line WL1 and an area to which the position of a selected word line SEL WL belongs is shorter, the level of the default voltage Vdef may increase.

For example, when the selected word line SEL WL belongs to an area including second to a-th word lines WL2 to WLa, the level of the default voltage Vdef may correspond to a 21-th voltage V21.

When the selected word line SEL WL belongs to an area including a+1-th to b-th word lines WLa+1 to WLb, the level of the default voltage Vdef may correspond to a 22-th voltage V22. Because the distance between the first word line WL1 and the area including the a+1-th to b-th word lines WLa+1 to WLb is shorter than the distance between the first word line WL1 and the area including the second to a-th word lines WL2 to WLa, the 21-th voltage V21 may be higher than the 22-th voltage V22.

Further, when the selected word line SEL WL belongs to an area including b+1-th to c-th word lines WLb+1 to WLc, the level of the default voltage Vdef may correspond to a 23-th voltage V23. Because the distance between the first word line WL1 and the area including the second to a-th word lines WL2 to WLa is shorter than the distance between the first word line WL1 and the area including the b+1-th to c-th word lines WLb+1 to WLc, the 22-th voltage V22 may be higher than the 23-th voltage V23.

Furthermore, when the temperature X of the memory device 100 is lower than first temperature TEMP1, the level of the first offset voltage Voff1 may correspond to a 31-th voltage V31.

When the temperature X of the memory device 100 is equal to or higher than the first temperature TEMP1 and lower than second temperature TEMP2, the level of the first offset voltage Voff1 may correspond to a 32-th voltage V32. Here, the 32-th voltage V32 may be lower than the 31-th voltage V31.

When the temperature X of the memory device 100 is equal to or higher than the second temperature TEMP2 and lower than third temperature TEMP3, the level of the first offset voltage Voff1 may correspond to a 33-th voltage V33. Here, the 33-th voltage V33 may be lower than the 32-th voltage V32.

In an embodiment, the level of the first voltage V1 may be determined to be a value obtained by adding the level of the first offset voltage Voff1 to the level of the default voltage Vdef.

In an embodiment, FIG. 8B is a diagram for describing an example in which the first voltage is determined based on the position of a selected word line and the program-erase cycle count of the memory block. The example of FIG. 8B in which a default voltage Vdef is determined is identical to the example of FIG. 8A in which the default voltage Vdef is determined, and thus a detailed description thereof will be omitted.

When the program-erase cycle count Y of the memory block is less than a first cycle count CYCLE1, the level of a second offset voltage Voff2 may correspond to a 41-th voltage V41.

When the program-erase cycle count Y of the memory block is equal to or greater than the first cycle count CYCLE1 and less than a second cycle count CYCLE2, the level of the second offset voltage Voff2 may correspond to a 42-th voltage V42. The 42-th voltage V42 may be higher than the 41-th voltage V41.

When the program-erase cycle count Y of the memory block is equal to or greater than the second cycle count CYCLE2 and less than a third cycle count CYCLE3, the level of the second offset voltage Voff2 may correspond to a 43-th voltage V43. The 43-th voltage V43 may be higher than the 42-th voltage V42.

In an embodiment, the level of the first voltage V1 may be determined to be a value obtained by adding the level of the second offset voltage Voff2 to the level of the default voltage Vdef.

In an embodiment, FIG. 8C is a diagram for describing an example in which the first voltage is determined based on the position of a selected word line, the temperature of the memory device, and the program-erase cycle count of the memory block. The examples of FIG. 8C, that is, the example in which the default voltage is determined, the example in which the first offset voltage Voff1 is determined, and the example in which the second offset voltage Voff2 is determined, are identical to the example of FIGS. 8A and 8B, that is, the example in which the default voltage Vdef is determined, the example in which the first offset voltage Voff1 is determined, and the example in which the second offset voltage Voff2 is determined, and thus detailed descriptions thereof will be omitted.

In an embodiment, the level of the first voltage V1 may be determined to be a value obtained by adding the level of the first offset voltage Voff1 and the level of the second offset voltage Voff2 to the level of the default voltage Vdef.

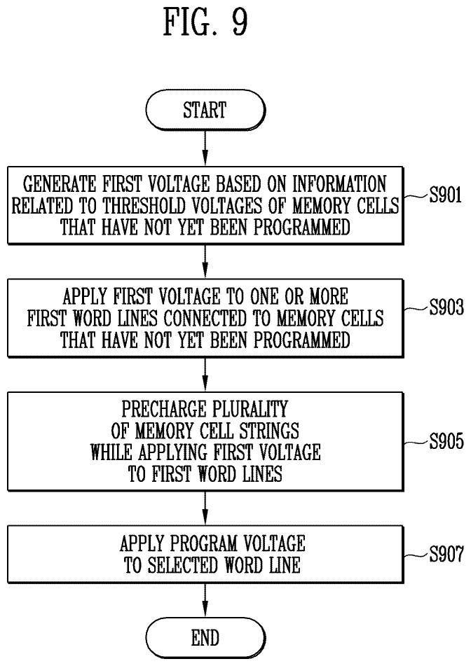

FIG. 9 is a flowchart illustrating a method of operating a memory device according to an embodiment of the present disclosure.

The method illustrated in FIG. 9 may be performed by, for example, the memory device 100 illustrated in FIG. 1.

Referring to FIG. 9, at operation S901, the memory device 100 may generate a first voltage based on information related to the threshold voltages of memory cells that have not yet been programmed by a program operation, among a plurality of memory cells.

At operation S903, the memory device 100 may apply the first voltage to one or more first word lines connected to the memory cells that have not yet been programmed, among a plurality of word lines.

At operation S905, the memory device 100 may precharge a plurality of memory cell strings while applying the first voltage to the first word lines.

At operation S907, the memory device 100 may apply a program voltage to a selected word line among the plurality of word lines.

According to the embodiments of the present disclosure, there are provided a memory device and a method of operating the memory device, which can obtain improved reliability by efficiently performing a precharge operation on memory cell strings. Furthermore, the embodiments may be combined to form additional embodiments.

What is claimed is:

1. A memory device comprising:
a memory block including a plurality of memory cell strings, each memory cell string including a source select transistor, a plurality of memory cells, and a drain select transistor sequentially coupled between a common source line and a bit line;
a peripheral circuit configured to perform a program operation of precharging the plurality of memory cell strings and applying a program voltage to a selected word line among a plurality of word lines coupled to the plurality of memory cells; and
a control logic configured to:
determine a first voltage based on information related to threshold voltages of memory cells that have not yet been programmed by the program operation, among the plurality of memory cells; and
control, while precharging the plurality of memory cell strings, the peripheral circuit to apply the first voltage to at least one first word line coupled to the memory cells which are not programmed yet, among the plurality of word lines, and apply a second voltage higher than the first voltage to the selected word line and at least one second word line coupled to memory cells programmed by the program operation, among the plurality of word lines.

2. The memory device according to claim 1, wherein the first voltage is higher than at least one of a ground voltage and the threshold voltages of the memory cells which are not programmed yet.

3. The memory device according to claim 1, wherein the information related to the threshold voltages of the memory cells which are not programmed yet includes at least one of a position of the selected word line, a temperature of the memory device, and a program-erase cycle count of the memory block.

4. The memory device according to claim 3, wherein the control logic is configured to store information on the first voltage determined based on the at least one of the position of the selected word line, the temperature of the memory device, and the program-erase cycle count of the memory block.

5. The memory device according to claim 3, wherein the position of the selected word line includes a distance from a word line coupled to memory cells to be programmed last, among the at least one first word line, to the selected word line.

6. The memory device according to claim 5, wherein the control logic is configured to increase a level of the first voltage as the distance between the word line coupled to the memory cells to be programmed last and the selected word line is shorter.

7. The memory device according to claim 5, wherein the control logic is configured to decrease a level of the first voltage as the temperature of the memory device increases.

8. The memory device according to claim 5, wherein the control logic is configured to increase a level of the first voltage as the program-erase cycle count of the memory block increases.

9. The memory device according to claim 5, wherein the control logic is configured to:
determine a default voltage based on the position of the selected word line; and
determine the first voltage by adding an offset voltage determined based on at least one of the temperature of the memory device and the program-erase cycle count of the memory block, to the default voltage.

10. A memory device comprising:
a memory block including a plurality of memory cell strings, each memory cell string including a plurality of memory cells coupled to a plurality of word lines, the memory block being coupled to the plurality of word lines, a source select line, and a drain select line;
a peripheral circuit configured to perform a program operation of precharging the plurality of memory cell strings while applying a first voltage to at least one first word line coupled to memory cells that have not yet been programmed among the plurality of word lines, and applying a program voltage to a selected word line among the plurality of word lines; and
a control logic configured to:
determine a default voltage based on a position of the selected word line;
determine an offset voltage based on at least one of a temperature of the memory device and a program-erase cycle count of the memory block; and
determine the first voltage by adding the offset voltage to the default voltage.

11. The memory device according to claim 10, wherein the control logic is configured to increase a level of the default voltage as the selected word line is closer to a word line coupled to memory cells to be programmed last, among the at least one first word line.

12. The memory device according to claim 10, wherein the control logic is configured to decrease a level of the offset voltage as the temperature of the memory device increases.

13. The memory device according to claim 10, wherein the control logic is configured to increase a level of the offset voltage as the program-erase cycle count of the memory block increases.

14. The memory device according to claim 10, wherein the first voltage is lower than a second voltage applied to the selected word line while the plurality of memory cell strings are precharged.

15. A method of operating a memory device, the memory device including a plurality of memory cell strings, each memory cell string including a source select transistor, a plurality of memory cells, and a drain select transistor sequentially coupled between a common source line and a bit line, the method comprising:
generating a first voltage based on information related to threshold voltages of memory cells that have not yet been programmed by a program operation, among the plurality of memory cells;
applying the first voltage to at least one first word line coupled to the memory cells which are not programmed yet, among the plurality of word lines;
precharging the plurality of memory cell strings while applying the first voltage to the at least one first word line; and
applying a program voltage to a selected word line among the plurality of word lines.

16. The method according to claim 15, wherein generating the first voltage comprises:
generating the first voltage based on at least one of a position of the selected word line, a temperature of the memory device, and a program-erase cycle count of a memory block including the plurality of memory cell strings.

17. The method according to claim 15, further comprising:
applying, while precharging the plurality of memory cell strings, a second voltage higher than the first voltage to the selected word line and at least one second word line coupled to memory cells programmed by the program operation, among the plurality of word lines.

18. The method according to claim 16, wherein the position of the selected word line includes a distance from a word line coupled to memory cells to be programmed last, among the at least one first word line, to the selected word line.

19. The method according to claim 18, further comprising increasing a level of the first voltage as the distance between the word line coupled to the memory cells to be programmed last and the selected word line is shorter.

20. The method according to claim 18, further comprising decreasing a level of the first voltage as the temperature of the memory device increases.

21. The method according to claim 18, further comprising increasing a level of the first voltage as the program-erase cycle count of the memory block increases.
